(19) United States
(12) Patent Application Publication
(10) Pub. No.: US 2024/0240355 A1
(43) Pub. Date: Jul. 18, 2024

(54) METHODS FOR PRODUCING SINGLE CRYSTAL SILICON WAFERS FOR INSULATED GATE BIPOLAR TRANSISTORS

(71) Applicant: GlobalWafers Co., Ltd., Hsinchu (TW)

(72) Inventors: Carissima Marie Hudson, St. Charles, MO (US); JaeWoo Ryu, Chesterfield, MO (US); Chi-Yung Chen, New Taipei City (TW); Chih-Hsun Wei, Hsinchu City (TW); Feng-Chien Tsai, Zhubei City (TW); Chung-Chi Hsiao, Taoyuan City (TW)

(21) Appl. No.: 18/411,957

(22) Filed: Jan. 12, 2024

Related U.S. Application Data
(60) Provisional application No. 63/480,146, filed on Jan. 17, 2023.

(51) Int. Cl. C30B 29/06; C30B 15/00; C30B 15/14; C30B 15/20; C30B 15/30; C30B 30/04; C30B 31/04

(52) U.S. Cl. CPC C30B 29/06; C30B 15/002; C30B 15/14; C30B 15/203; C30B 15/30; C30B 30/04; C30B 31/04

(57) ABSTRACT

Methods for producing single crystal silicon wafers for use in insulated gate bipolar transistors are disclosed. The methods may involve determining the radial profile of a ratio between (i) a growth velocity, v, and (ii) an axial temperature gradient, G for an ingot with relatively low oxygen. Based on the radial v/G profile, a nitrogen concentration which widens the v/G window to produce Perfect Silicon free of COP and gate oxide failures may be selected.

### CROSS-REFERENCE TO RELATED APPLICATIONS

This application claims the benefit of U.S. Provisional Patent Application No. 63/480,146, filed Jan. 17, 2023, which is incorporated herein by reference in its entirety.

### TECHNICAL FIELD

The field of the disclosure relates to methods for producing single crystal silicon wafers for use in insulated gate bipolar transistors.

### BACKGROUND

Single crystal silicon, which is the starting material for most processes for the fabrication of semiconductor electronic components, is commonly prepared by the so-called Czochralski (“Cz”) method. According to the Czochralski method, polycrystalline silicon (“polysilicon”) is charged to a crucible and melted. A seed crystal is brought into contact with the molten silicon and a single crystal ingot is grown by slow extraction.

Oxygen is typically introduced into the silicon melt from the crucible, which is typically made of quartz (SiO₂). During the solidification process, oxygen from the melt is incorporated into silicon crystal ingot. The oxygen (which may be referred to as interstitial oxygen or simply “Oi”) can be beneficial to the silicon ingot and the wafers and devices made from that ingot, however it may also be detrimental and in some cases may also contribute to the formation of various defects in wafers produced from the ingots, reducing the yield of semiconductor devices fabricated using those wafers. For example, insulated-gate bipolar transistors (IGBTs) typically require a low oxygen concentration in order to achieve high resistivity and to avoid formation of P-N junctions. Single crystal silicon wafers used for IGBTs are typically free of crystal originated particles (COP) and are free of gate oxide integrity failures (i.e., which is commonly referred to as “Perfect Silicon” material). Lower oxygen wafers suitable for IGBT are difficult to produce because reducing the oxygen concentration increases the difficulty in producing COP free wafers (and may involve specific thermal/growth conditions).

A need exists for methods for preparing single crystal silicon ingots from which wafers may be sliced that have a relatively low oxygen concentration and that are free of COP and free of gate oxide integrity failures.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for producing single crystal silicon wafers for insulated gate bipolar transistors (IGBT). A single crystal silicon ingot is produced. The single crystal silicon ingot has a radial profile of a ratio between (i) a growth velocity, v, and (ii) an axial temperature gradient, G. The single crystal silicon ingot is produced by determining a radial v/G profile of the single crystal silicon ingot. An ingot nitrogen concentration at which the ingot is free of gate oxide integrity failures across the ingot radius is selected based on the radial v/G profile of the ingot. Polycrystalline silicon is added to a crucible disposed within a growth chamber of an ingot puller apparatus. The polycrystalline silicon is heated to cause a silicon melt to form in the crucible. Nitrogen is added to the silicon melt to achieve the selected ingot nitrogen concentration. A single crystal silicon ingot doped with nitrogen is pulled from the melt. A plurality of wafers are sliced from the single crystal silicon ingot. Each wafer of the plurality of wafers has an oxygen concentration of less than 2.75×10¹⁷ atoms/cm³ and is free of crystal originated particles and is free of gate-oxide integrity failures.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section schematic of an insulated gate bipolar transistor (IGBT) device;

FIG. 2 is a cross-section of an ingot puller apparatus during ingot growth;

FIG. 3 is a diagram showing ingot defect bands as a function of v/G and nitrogen concentration;

FIG. 4 is a diagram showing ingot defect bands as a function of v/G and nitrogen concentration and showing the window for the absence of gate-oxide integrity failures (“GOI failure”) at typical oxygen concentrations (e.g., 3×10¹⁷ atoms/cm³ to 6×10¹⁷ atoms/cm³);

FIG. 5 is a diagram showing ingot defect bands as a function of v/G and nitrogen concentration and showing the window for the absence of gate-oxide integrity failures (“GOI failure”) at low oxygen concentrations (e.g., less than 3×10¹⁷ atoms/cm³);

FIG. 6 is a diagram showing the defect bands shown in FIG. 5 and showing radial defect bands for no nitrogen doping and with nitrogen doping for well controlled v/G;

FIG. 7 is a diagram showing the defect bands shown in FIG. 5 and showing radial defect bands for no nitrogen doping and with nitrogen doping for variation of the radial defect bands under low Oi conditions; and

FIG. 8 is a graph showing the v/G ratio between crystal center and the R/2 position and the GOI failure free region as a function of nitrogen concentration.

Corresponding reference characters indicate corresponding parts throughout the drawings.

### DETAILED DESCRIPTION

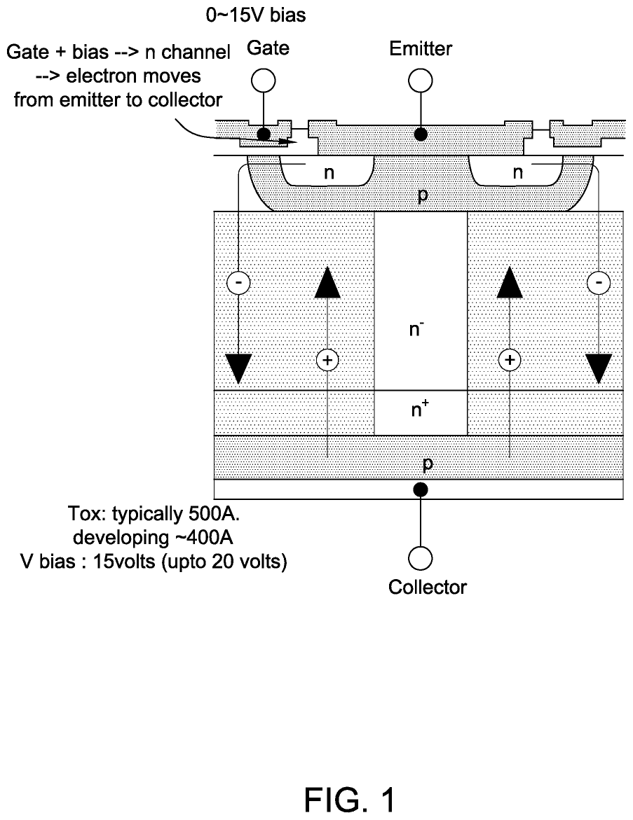

Provisions of the present disclosure relate to methods for producing single crystal silicon wafers for use in insulated gate bipolar transistors (IGBT). An example IGBT device is shown in FIG. 1. Such devices may include at least four layers (with at least one of the layers being a chip singlated from a wafer produced by an embodiment of the methods described herein). The transistor may include a gate electrode, collector electrode, and emitter.

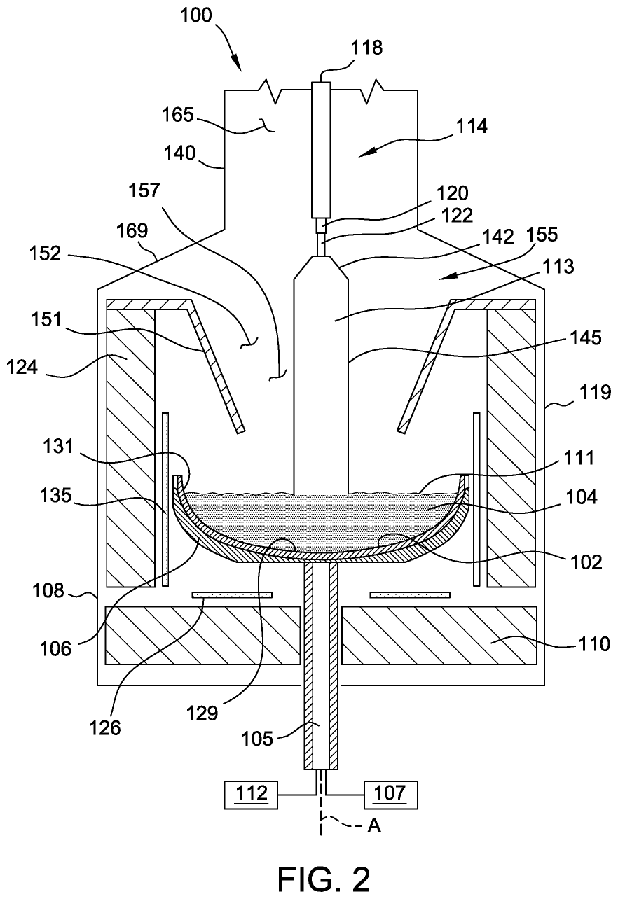

The single crystal silicon wafers of the present disclosure are sliced from a single crystal silicon ingot. In accordance with embodiments of the present disclosure and with reference to FIG. 2, an example ingot puller apparatus (or more simply “ingot puller”) for producing a single crystal silicon ingot is indicated generally as “100”. The ingot puller apparatus 100 includes a crucible assembly 102 (or more simply “crucible”) for holding a melt 104 of semiconductor or solar-grade material silicon. The crucible assembly 102 is supported by a susceptor 106.

The ingot puller apparatus 100 includes a crystal puller housing 108 that defines a growth chamber 152 for pulling a silicon ingot from the silicon melt 104 along a pull axis A. The growth chamber 152 includes two portions-a lower growth chamber 155 (or simply “lower chamber”) and an upper growth chamber 165 (or simply “upper chamber”) disposed above the lower growth chamber 155. The hotzone of the ingot puller apparatus 100 (e.g., crucible, reflector assembly, susceptor, heaters, and the like) is disposed within the lower chamber 155. During ingot growth, the ingot 113 is pulled through the lower chamber 155 and continues to be pulled through the upper chamber 165 as the ingot lengthens.

The crystal puller housing 108 includes a domed lower segment 119 that defines the lower chamber 155 and an upper segment 140 that defines the upper chamber 165. The lower domed segment 119 includes a dome-shaped portion 169 which tapers in size to the diameter of the upper segment 140. The upper segment 140 is generally cylindrical in shape and includes a lower end 159 and an upper end 163. The upper segment 140 of the crystal puller housing 108 is removably connected to the lower segment 119 (e.g., by fasteners, gaskets or the like).

The crucible assembly 102 is disposed in the lower chamber 155. The crucible assembly 102 has a sidewall 131 and floor 129 and rests on a susceptor 106. The susceptor 106 is supported by a shaft 105. The susceptor 106, crucible assembly 102, shaft 105, and ingot 113 have a common longitudinal axis or “pull axis” A.

A pulling mechanism 114 is provided within the ingot puller apparatus 100 for growing and pulling an ingot 113 from the melt 104. The pulling mechanism 114 includes a pull cable 118, a seed holder or chuck 120 coupled to one end of the pull cable 118, and a seed crystal 122 coupled to the chuck 120 for initiating crystal growth. One end of the pull cable 118 is connected to a pulley (not shown) or a drum (not shown) of the pulling mechanism 114 and the other end is connected to the chuck 120 that holds the seed crystal 122. The pulling mechanism 114 includes a motor that rotates the pulley or drum.

In operation, the seed crystal 122 is lowered to contact the surface 111 of the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A during the growth process. For example, the crucible assembly 102 may be at a lowest position (near the bottom heater 126) in which a charge of solid-phase silicon 133 previously added to the crucible assembly 102 is melted. Crystal growth commences by contacting the melt 104 with the seed crystal 122 and lifting the seed crystal 122 by the pulling mechanism 114.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit may rotate the pulling cable 118 in the same direction in which crucible drive unit rotates the crucible assembly 102.

The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible floor 129. The crucible assembly 102 may be moved to be in relatively close proximity to the bottom heater 126 to melt the solid silicon charged to the crucible assembly 102.

According to the Czochralski single crystal growth process, a quantity of solid-phase silicon such as polycrystalline silicon, or “polysilicon”, is initially charged to the crucible assembly 102. The semiconductor or solar-grade solid silicon that is introduced into the crucible assembly 102 is melted by heat provided from one or more heating elements. Once the melt 104 is fully formed, the seed crystal 122 is lowered and contacted with the surface 111 of the melt 104. The pulling mechanism 114 is operated to pull the seed crystal 122 from the melt 104. The resulting ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The crystal growth process may be a batch process in which solid silicon is initially added to the crucible assembly 102 to form a silicon melt without additional solid-silicon being added to the crucible assembly 102 during crystal growth. In other embodiments, the crystal growth process is a continuous Czochralski process in which an amount of silicon is added the crucible assembly 102 during ingot growth.

The ingot puller apparatus 100 includes a side heater 135 and a susceptor 106 that encircles the crucible assembly 102 to maintain the temperature of the melt 104 during crystal growth. The side heater 135 is disposed radially outward to the crucible sidewall 131 as the crucible assembly 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a reflector assembly 151. The reflector assembly 151 includes an opening 157 through which the single crystal silicon ingot 113 is pulled during ingot growth. The ingot puller apparatus 100 may include an inert gas system to introduce and withdraw an inert gas such as argon from the growth chamber 152.

The illustrated ingot puller apparatus 100 is an example and any ingot puller apparatus 100 suitable for producing a single crystal silicon ingot may be used unless stated otherwise.

Wafers may be sliced from the single crystal silicon ingot 113 (e.g., by a diamond wire saw).

The resulting wafers may have a diameter of 200 mm, eater than 200 mm, 300 mm, or greater than 300 mm. In some embodiments, the wafers have a diameter of 300 mm. The wafers may be p-type or n-type.

The wafers may have a relatively low oxygen content such that they are suitable for use in IGBT devices. For example, the wafers may have an oxygen concentration of less than 2.75×10¹⁷ atoms/cm³ or even less than 2.2×10¹⁷ atoms/cm³. The oxygen content may be less than 5.5 ppma or even less than 5.0 ppma.

Various control parameters may be selected during ingot growth to achieve such relatively low concentration silicon ingots. For example, any combination of high magnetic field strength (e.g., to suppress silicon melt flow), slow crucible rotation (e.g., to increase evaporation of oxygen from the melt), relatively low crucible bottom temperatures (e.g., to reduce quartz crucible dissolution) may be used. In some embodiments, a cusp magnetic field is applied to the melt. In some embodiments, the crystal rotation rate may be between 6 rpm and 15 rpm, and/or the crucible rotation rate may be between 0.5 rpm and 2.5 rpm, and/or the magnetic field strength may be between 0.02 and 0.075 Tesla at an edge of the silicon ingot at a melt-solid interface and between 0.05 and 0.20 Tesla at a wall of the crucible (e.g., with the parameters being changed/tuned in a second stage of ingot growth to maintain relatively low oxygen over the ingot length).

In other embodiments, a horizontal magnetic field is applied to silicon melt. A plurality of process parameters may be controlled during application of the horizontal magnetic field. For example, the position of the maximum gauss plane of the horizontal magnetic field may be maintained above the melt free surface (e.g., from 20 mm to 250 mm above the melt free surface). Alternatively or in addition, the horizontal magnetic field may be applied at a magnetic flux density of from 0.1 Tesla to about 0.4 Tesla and/or the crucible may be rotated (opposite or the same direction of the ingot) at a rate from 0.1 RPM to 5.0 RPM.

The growth conditions may be selected among the conditions disclosed in U.S. patent Publication No. 2018/0355509 and/or U.S. patent Publication No. 2022/0349087, both of which are incorporated herein by reference for all relevant and consistent purposes.

The conditions which promote growth of low oxygen ingots may increase difficulty in growing Perfect Silicon material (e.g., the process window at which a ratio of the growth velocity, v, and an axial temperature gradient, G may be controlled to produce Perfect Silicon is relatively narrow). In accordance with embodiments of the present disclosure, the ingot may be doped with nitrogen by adding nitrogen to the silicon melt to increase the v/G process window for Perfect Silicon. Axial v/G control may be achieved by controlling the reflector height (Hr) and by control of seed lift.

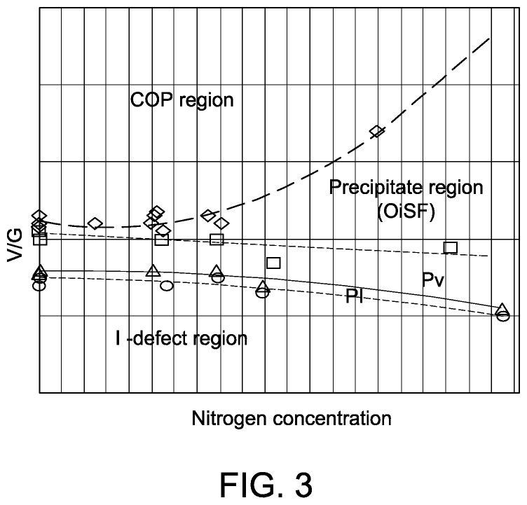

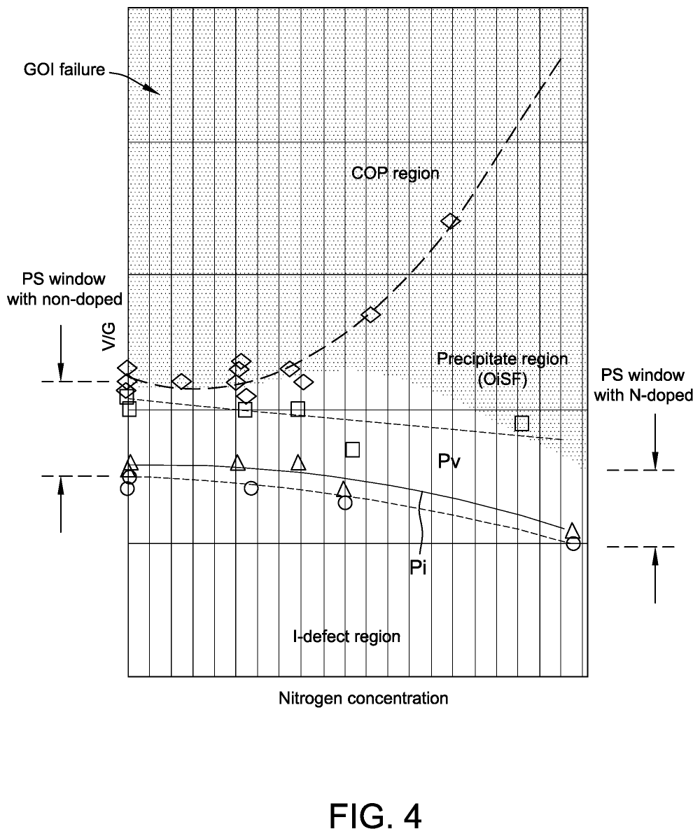

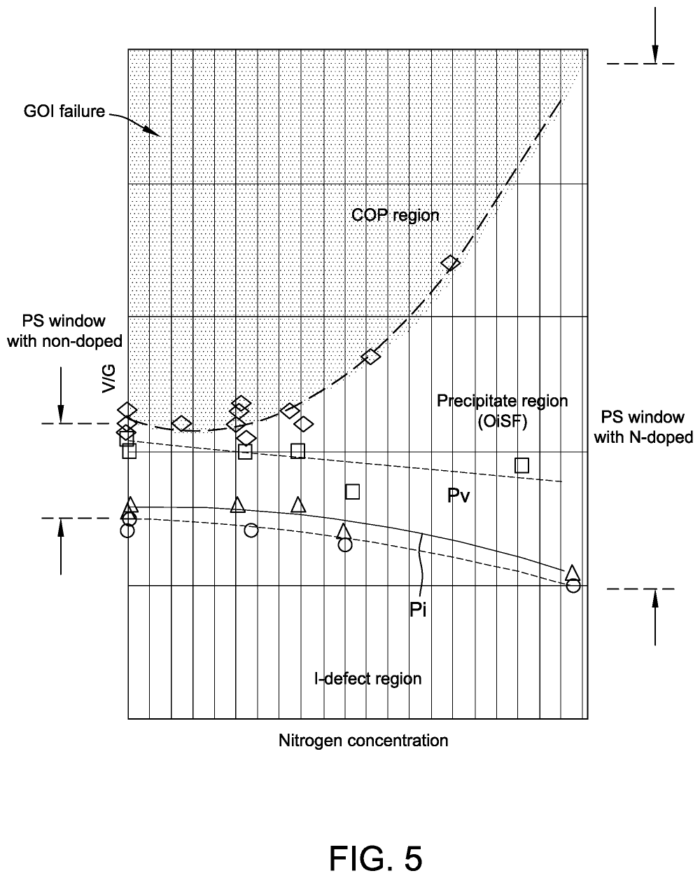

As shown in FIG. 3, by adding nitrogen to the ingot, the COP region decreases for a given v/G while the oxygen precipitate band increases. With additional nitrogen, the source of GOI degradation changes from COP to the combination of COP and oxygen precipitates (e.g., the high density of oxygen precipitates in heavily doped nitrogen consumes the excess free vacancies so it increases the stress field at the interface between the defect and the silicon matrix) as shown in FIG. 4 (at typical oxygen content such as 3×10¹⁷/cm³ to 6×10¹⁷/cm³). Referring now to FIG. 5, at lower oxygen (e.g., less than 3×10¹⁷/cm³), formation and growth of oxygen precipitates are limited, even with nitrogen doping, which lessens leakage issues resulting in a larger Perfect Silicon (PS) window.

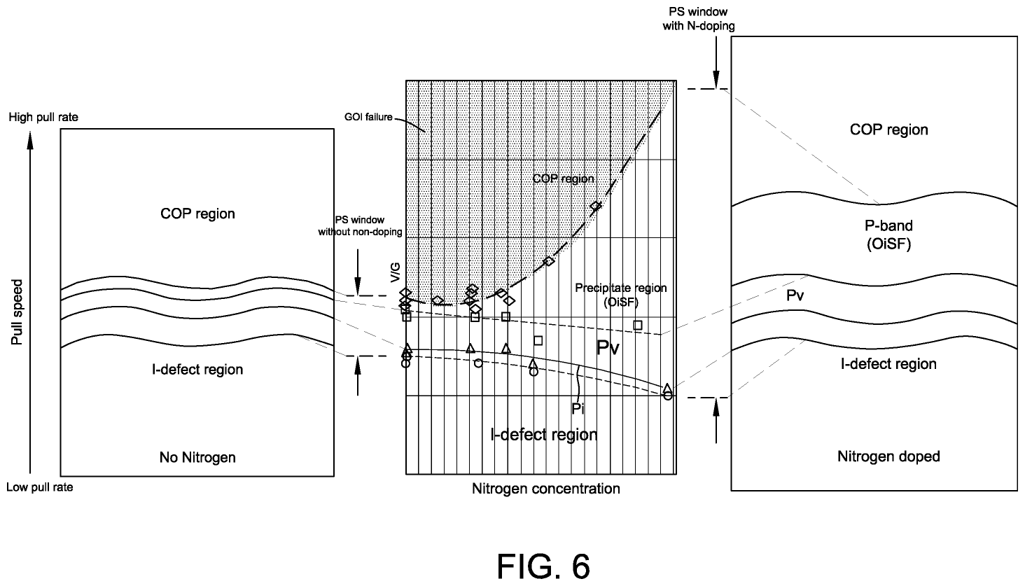

FIG. 6 shows the radial defect shape in the low oxygen conditions of FIG. 5 for no nitrogen doping and nitrogen doping for well controlled v/G. As shown in FIG. 6, the radial defect shape is not flat and varies radially due to radial variation in v/G.

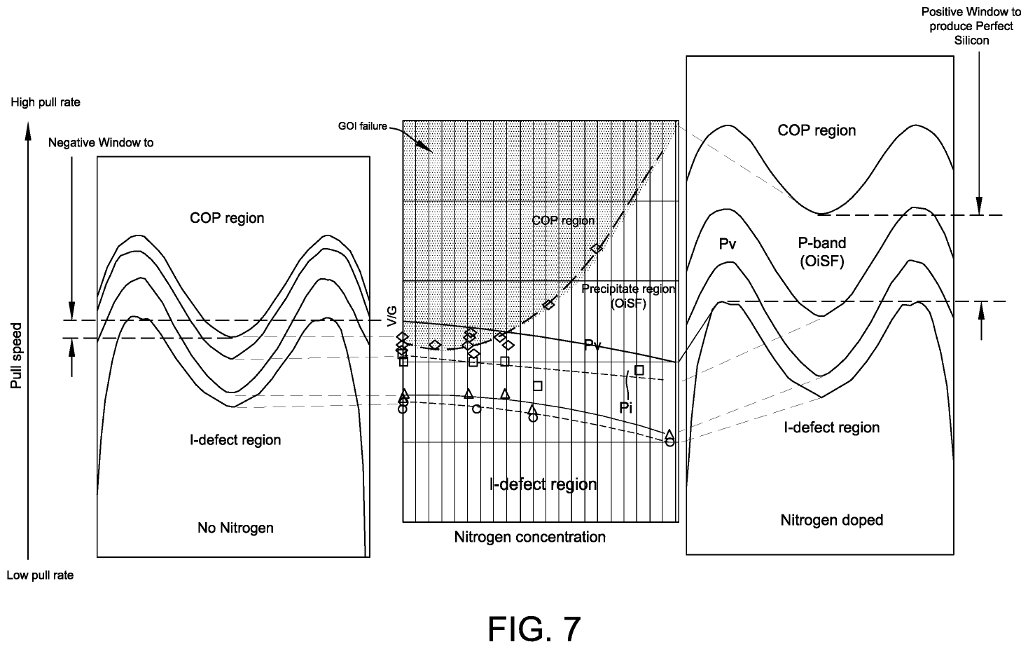

Because of the radial defect band structure of low oxygen processes, the real process window of low oxygen is lower than the ideal case of FIG. 6. The critical v/G for interstitial defects at a point halfway between the center and a circumferential edge of the ingot (“the R/2 position”) is larger than that of the crystal center. As shown in the left panel of FIG. 7, in the case of no N-doping, the process window to produce good GOI yield is not available. To avoid I-defects at the R/2 position, higher pull speed is required leading to a center core pattern where the COP is detected. By adding nitrogen, the precipitate region is widened and GOI degradation is reduced or eliminated at the precipitate region due to low oxygen. The pull speed range between the R/2 position and the ingot center can produce a COP free window, as shown in the right panel of FIG. 7 (i.e., free of gate-oxide integrity failures of a size greater than 8 MVcm.

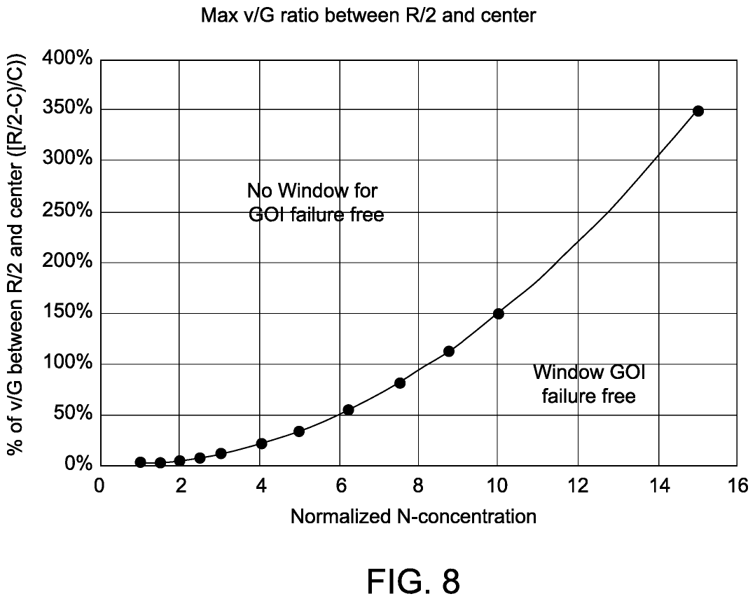

The nitrogen concentration may be selected to achieve GOI failure free material across the radius of the ingot based on the radial v/G profile. In some embodiments, a difference between the ratio of v/G at the center of the ingot and the ratio of v/G at the R/2 position is determined. The nitrogen concentration may be selected based on the determined difference between the ratio of v/G at the center of the ingot and the ratio of v/G at the R/2 position such that the ingot is free of gate oxide integrity failures across the ingot radius (e.g., nitrogen may be selected according to the function shown in FIG. 8).

The ratio v/G at the R/2 position and at the center of the crystal may be determined empirically, such as by an axial ramping velocity test method. A full-diameter test ingot is grown in the ingot puller apparatus (i.e., the same ingot puller apparatus at which the product ingots are grown) with the growth velocity being ramped up during growth of the test ingot. The growth velocity, v, at a given radial position of the test ingot (e.g., the R/2 position or the center of the ingot) at which a transition from interstitial-defects begins (i.e., the velocity at which critical v/G occurs) is then determined. The ramped velocity axial test shows where the I-defect region forms at the radial positions (center, edge, R/2) and, from this information, the ratio of v/G between the R/2 position and the center of the ingot can be calculated. As the critical v/G is a pre-determined or known parameter (for a given doping level), the axial temperature gradient, g, may be calculated for the radial position based on the growth velocity, v, at which the interstitial-defect band terminates at the given radial position in the test ingot.

The position of the transition from the interstitial-dominant region at the given radial position may be determined by vertical cut slabbing and observation of the slab to determine the position at which the I-defect band stop and determination of the growth velocity, v, at this position. Alternatively, the position at which interstitial defects stop may be determined by slicing wafers from the ingot and observation of the wafers to determine the position at which the interstitial-defects stop.

Once a product ingot has been grown by a method of the present disclosure, a plurality of wafers are sliced from the single crystal silicon ingot, optionally after one or more additional processing steps (e.g., ingot grinding). Singulation may be performed to divide the wafers into a plurality of semiconductor chips. An insulated gate bipolar transistor may be produced in which at least one of layers of the transistor is a semiconductor chip singlated from the wafer.

Compared to conventional methods for producing single crystal silicon wafers for insulated gate bipolar transistors, the methods of the present disclosure have several advantages. By controlling the growth parameters such that ingot oxygen concentration is less than 2.75×10¹⁷ atoms/cm³, the resulting wafers are suitable for low-oxygen IGBT applications. By determining the radial v/G profile of the single crystal silicon ingot (e.g., at position R/2 and at the center) and comparing the ratio of v/G between the R/2 position and the center, the appropriate nitrogen concentration at which the ingot is GOI failure free and suitable for IGBT may be selected. Because the magnitude of variation of the radial defect bands is dependent on the puller hotzone geometry (e.g., heater position, insulation design, and the like) and because other parameters are set to achieve low oxygen (e.g., crucible rotation, magnetic field strength, heater power, and the like), by determining the difference in v/G between the center and at the R/2 position, the difference may be correlated to the amount of nitrogen doping that should be used to achieve Perfect Silicon across the wafer radius for the particular ingot puller and for the given growth conditions to achieve low oxygen.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for producing single crystal silicon wafers for insulated gate bipolar transistors (IGBT), the method comprising:
producing a single crystal silicon ingot, the single crystal silicon ingot having a radial profile of a ratio between (i) a growth velocity, v, and (ii) an axial temperature gradient, G, the single crystal silicon ingot being produced by:
determining a radial v/G profile of the single crystal silicon ingot;
selecting an ingot nitrogen concentration at which the ingot is free of gate oxide integrity failures across the ingot radius based on the radial v/G profile of the ingot;
adding polycrystalline silicon to a crucible disposed within a growth chamber of an ingot puller apparatus;
heating the polycrystalline silicon to cause a silicon melt to form in the crucible;
adding nitrogen to the silicon melt to achieve the selected ingot nitrogen concentration; and
pulling a single crystal silicon ingot doped with nitrogen from the melt; and
slicing a plurality of wafers from the single crystal silicon ingot, each wafer of the plurality of wafers having an oxygen concentration of less than 2.75×10¹⁷ atoms/cm³, being free of crystal originated particles and being free of gate-oxide integrity failures.

2. The method as set forth in claim 1 wherein selecting an ingot nitrogen concentration at which the ingot is free of gate oxide integrity failures across the ingot radius based on the radial v/G profile of the ingot comprises:
determining a difference between the ratio of v/G at the center of the ingot and the ratio of v/G at a point halfway between the center and a circumferential edge of the ingot; and
selecting a nitrogen concentration at which the ingot is free of gate oxide integrity failures across the ingot radius based on the determined difference between the ratio of v/G at the center of the ingot and the ratio of v/G at a point halfway between the center and a circumferential edge of the ingot.

3. The method as set forth in claim 2 wherein the nitrogen concentration at which the ingot is free of gate oxide integrity failures across the ingot radius is determined based on a ratio between the ratio of v/G at the center of the ingot and the ratio of v/G at a point halfway between the center and a circumferential edge of the ingot.

4. The method as set forth in claim 1 wherein the radial v/G profile is determined empirically by a ramping test method comprising:
pulling a test ingot in the ingot puller apparatus, the test ingot being grown while ramping the growth velocity;
determining the growth velocity, v, at a given radial position of the test ingot at a transition from interstitial-defects; and
calculating the axial temperature gradient, g, at the radial position based on a predetermined critical v/G at the transition from interstitial-defects and the growth velocity, v, at which the transition from interstitial-defects was observed at the radial position in the test ingot.

5. The method as set forth in claim 4 wherein the radial position is the R/2 position.

6. The method as set forth in claim 5 wherein v/G is also determined at the center of the ingot.

7. The method as set forth in claim 4 wherein the growth velocity, v, at a given radial position of the test ingot at the transition from interstitial-defects is determined by vertical cut slabbing and observation of the slab to determine the position at which the transition from interstitial-defects occurs and determination of the growth velocity, v, at the position at which the transition from interstitial-defects occurs.

8. The method as set forth in claim 4 wherein the growth velocity, v, at a given radial position of the test ingot at the transition from interstitial-defects is determined by slicing wafers from the ingot and observation of the wafers to determine the position at which the transition from interstitial-defects occurs and determination of the growth velocity, v, at the position at which the transition from interstitial-defects occurs.

9. The method as set forth in claim 1 wherein a concentration of nitrogen in each wafer is at least 2×10¹³ atoms/cm³.

10. The method as set forth in claim 1 wherein the concentration of oxygen in each wafer is less than 2.2×10¹⁷ atoms/cm³.

11. The method as set forth in claim 1 wherein each wafer of the plurality of wafers has an oxygen content of less than 5.5 ppma.

12. The method as set forth in claim 1 wherein each wafer of the plurality of wafers has an oxygen content of less than 5.0 ppma.

13. The method as set forth in claim 1 wherein one or more growth parameters selected from a crystal rotation rate, a crucible rotation rate and a magnetic field strength are selected to achieve the oxygen concentration in each of the plurality of wafers of less than 2.75×10¹⁷ atoms/cm³.

14. The method as set forth in claim 13 wherein:
a cusp magnetic field is applied to the silicon melt;
the crystal rotation rate is between 6 rpm and 15 rpm;
the crucible rotation rate is between 0.5 rpm and 2.5 rpm; and
the magnetic field strength is 0.02 and 0.075 Tesla at an edge of the silicon ingot at a melt-solid interface and between 0.05 and 0.20 Tesla at a wall of the crucible.

15. The method as set forth in claim 13 wherein:
a horizontal magnetic field is applied to the silicon melt with a maximum gauss plane of the horizontal magnetic field being maintained from 20 mm to 250 mm above a melt free surface;
the crucible rotation rate is between 0.1 rpm to 5.0 rpm; and
the magnetic flux density is from 0.1 Tesla to about 0.4 Tesla.

16. The method as set forth in claim 1 wherein the plurality of wafers are free of gate-oxide integrity failures of a size greater than 8 MVcm.

17. The method as set forth in claim 1 wherein the single crystal silicon ingot is grown in a batch process in which silicon is not added to the crucible during growth of the single crystal silicon ingot.

18. The method as set forth in claim 1 wherein the single crystal silicon ingot is grown in a continuous process in which silicon is added to the crucible during growth of the single crystal silicon ingot.

19. The method for producing an insulated gate bipolar transistor comprising:
singulating a wafer produced by the method of claim 1 into a plurality of semiconductor chips; and
forming an insulated gate bipolar transistor having at least four layers, wherein at least one of the layers comprises a semiconductor chip singlated from the wafer, the insulated gate bipolar transistor comprising a gate electrode, collector electrode, and emitter.
